(19) United States
(12) Patent Application Publication
(10) Pub. No.: US 2025/0264536 A1
(43) Pub. Date: Aug. 21, 2025

(54) METHOD FOR ESTIMATING CHARGING RATE OF BATTERY

(71) Applicant: TOYOTA JIDOSHA KABUSHIKI KAISHA, Toyota-shi (JP)

(72) Inventor: Takuya MIWA, Toyota-shi (JP)

(73) Assignee: TOYOTA JIDOSHA KABUSHIKI KAISHA, Toyota-shi (JP)

(21) Appl. No.: 18/962,117

(22) Filed: Nov. 27, 2024

(30) Foreign Application Priority Data
Feb. 21, 2024 (JP) 2024-024419

(51) Int. Cl. G01R 31/3835

(52) U.S. Cl. CPC G01R 31/3835

(57) ABSTRACT

A method for estimating a charging rate of a battery including: acquiring an SOC-OCV curve line for the battery having a charge/discharge hysteresis of Δ0.06V to 0.24V, calculating an average voltage of OCV for each SOC from the acquired result, and recording the relation between the calculation result and the SOC; performing continuous charging or continuous discharging on the battery; performing return discharging that is discharging of 3% or more of a total capacity of the battery when the continuous charging has been performed, and performing return charging that is charging of 3% or more of the total capacity of the battery when the continuous discharging has been performed; and measuring the OCV of the battery and checking the value of the OCV against the recorded relation between the SOC and the average voltage of the OCV to acquire an estimated value of the charging rate of the battery.

### CROSS-REFERENCE TO RELATED APPLICATION

This application claims priority to Japanese Patent Application No. 2024-024419 filed on Feb. 21, 2024, incorporated herein by reference in its entirety.

### BACKGROUND

### 1. Technical Field

The present disclosure relates to a method for estimating a charging rate (remaining capacity) of a battery.

### 2. Description of Related Art

Japanese Unexamined Patent Application Publication No. 2017-227653 discloses a method for measuring a closed circuit voltage (CCV) of a battery and estimating a battery charging rate from respective patterns according to a charging mode and a discharging mode.

### SUMMARY

However, according to conventional methods, when a battery deteriorates, the estimation accuracy for the charging rate (remaining capacity) of a battery deteriorates.

The present disclosure has been made in consideration of the above-mentioned circumstances, and has an object to provide a method that can maintain the accuracy of estimating the battery charging rate (remaining capacity) even when the battery deteriorates.

As a result of extensive research by the inventor, the inventor has found that the above estimation accuracy is particularly degraded in batteries with large charge/discharge hysteresis (for example, when Si is used as a negative electrode active material). A method disclosed in the present disclosure can also be applied to various secondary batteries such as solid-state batteries, semi-solid-state batteries, and batteries containing electrolytes.

The present application discloses a method for estimating a charging rate of a battery, the method including a step of acquiring an SOC-OCV curve line for the battery having a charge/discharge hysteresis of Δ0.06V to 0.24V, calculating an average voltage of OCV for each SOC from an acquired result, and recording a relation between a calculation result and the SOC, a step of performing continuous charging or continuous discharging on the battery, a step of performing return discharging that is discharging of 3% or more of a total capacity of the battery when the continuous charging has been performed, and performing return charging that is charging of 3% or more of the total capacity of the battery when the continuous discharging has been performed, and a step of measuring the OCV of the battery and checking the value of the OCV against the recorded relation between the SOC and the average voltage of the OCV to acquire an estimated value of the charging rate of the battery.

Here, SOC and OCV are well known, and SOC means the state of charge of the battery, and OCV means the open circuit voltage.

The return discharging and the return charging may be set from 4% to 6%.

After the return discharging and the return charging have been performed, charging and discharging of the battery may be suspended for a predetermined period of time, and then an estimated value of the battery charge rate may be acquired.

According to the present disclosure, the accuracy of the estimation of the charging rate (remaining capacity) of a battery can be maintained even when the battery deteriorates.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram showing a configuration of an estimation device 20;

FIG. 2 is a graph showing a charge/discharge hysteresis and an average voltage curve line of an SOC-OCV characteristic of a battery; and

FIG. 3 is a diagram showing flow of an SOC estimation method S10 for the battery.

### DETAILED DESCRIPTION OF EMBODIMENTS

### 1. Control Device for Battery

A method for estimating the charging rate (remaining capacity) of a battery of the present disclosure is executed by an estimation device as one embodiment. An estimation device 20 for a battery according to one example will be described with reference to the drawings.

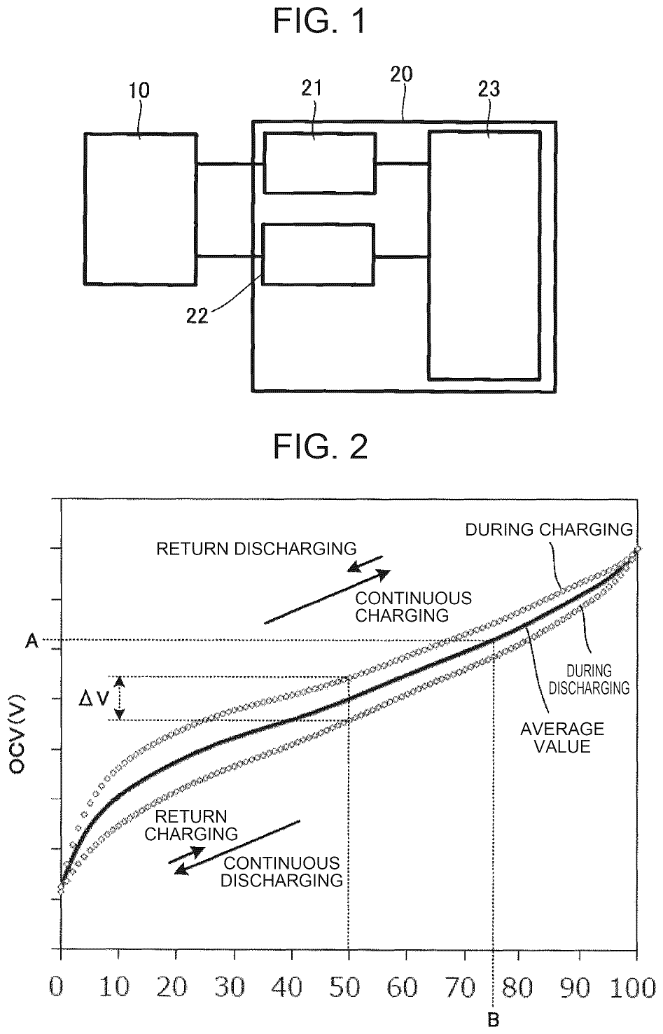

FIG. 1 is a block diagram showing a configuration of the estimation device 20 according to the present embodiment. As shown in FIG. 1, the estimation device 20 includes a charging/discharging unit 21, a voltage measurement unit 22, and a controller 23.

The charging/discharging unit 21 is a portion which is electrically connected to the battery 10, and receives electric power from a power supply device (not shown) or the like to charge and discharge the battery 10. The charging/discharging unit 21 has a switch, and is configured to switch between charging and discharging by switching the switch. The charging/discharging unit 21 is also electrically connected to the controller 23, and the switching of the switch (switching between charging and discharging) is performed by a command from the controller 23.

The voltage measurement unit 22 is a portion that is electrically connected to the battery 10 to measure OCV of the battery 10. Therefore, the voltage measurement unit 22 is configured with a voltmeter or the like. The voltage measurement unit 22 is also electrically connected to the controller 23, and is configured such that the controller 23 can obtain voltage data obtained by the voltage measurement unit 22.

The controller 23 is a device for controlling the above-mentioned components, storing necessary data, and calculating a charging rate in order to execute the method for estimating a battery charging rate described later. The controller 23 can typically be configured by a computer.

The computer includes a central processing unit (CPU) which is a processor, a random access memory (RAM) which functions as a working area, a read-only memory (ROM) which serves as a storage unit, a receiving unit which is an interface for receiving information into the computer whether wired or wireless, and an output unit which is an interface for sending information from the computer to the outside whether wired or wireless. For example, the voltage measurement unit 22 is connected to the receiving unit, and a charging/discharging unit 21 is connected to the output unit.

The computer stores a computer program for executing, as specific instructions, respective steps of a method for estimating the battery charging rate of the present disclosure. In the computer, CPU, RAM, and ROM as hardware resources and the computer program cooperate with each other. Specifically, the CPU executes the computer program recorded in the ROM with the RAM functioning as a work area, whereby giving instructions to the charging/discharging unit 21 via the output unit to control charging and discharging as described later, and performs a calculation based on a signal representing the voltage obtained via the receiving unit. Information obtained or created by the CPU is stored in the RAM.

### 2. Battery

In the present disclosure, the battery 10 to be estimated for the battery charging rate may include various secondary batteries including solid-state batteries such as an all-solid-state battery and a semi-solid battery, and a battery containing electrolyte. Among them, there can be mentioned batteries with large charge/discharge hysteresis, specifically batteries with charge/discharge hysteresis in the range of Δ0.06V to Δ0.24V. Here, the charge/discharge hysteresis means the difference (voltage difference) between the charge OCV and the discharge OCV at a certain SOC. Furthermore, the batteries with charge/discharge hysteresis in the range of Δ0.06V to Δ0.24V mean that the voltage difference is within this range at any SOC or all SOCs when the SOC is from 1% to 99%.

FIG. 2 shows the relation between SOC and OCV according to one example. In this figure, the horizontal axis represents SOC (%) and the vertical axis represents OCV (V). For example, the charge/discharge hysteresis at an SOC of 50% is ΔV in FIG. 2. In other words, the relation between the SOC and the OCV changes greatly between charging and discharging.

When the battery is an all-solid-state battery, the charge/discharge hysteresis is particularly large, and is particularly noticeable when Si is contained as the negative electrode active material. One example is one in which the positive electrode active material is LiNi_{1/3}Co_{1/3}Mn_{1/3}O₂, the negative electrode active material is Si, and the electrolyte is Li₃PS₄.

However, even secondary batteries using semi-solid batteries or electrolytes may have large charge/discharge hysteresis, and in such cases the method disclosed in the present disclosure is useful.

### 3. Method for Estimating Battery Charging Rate

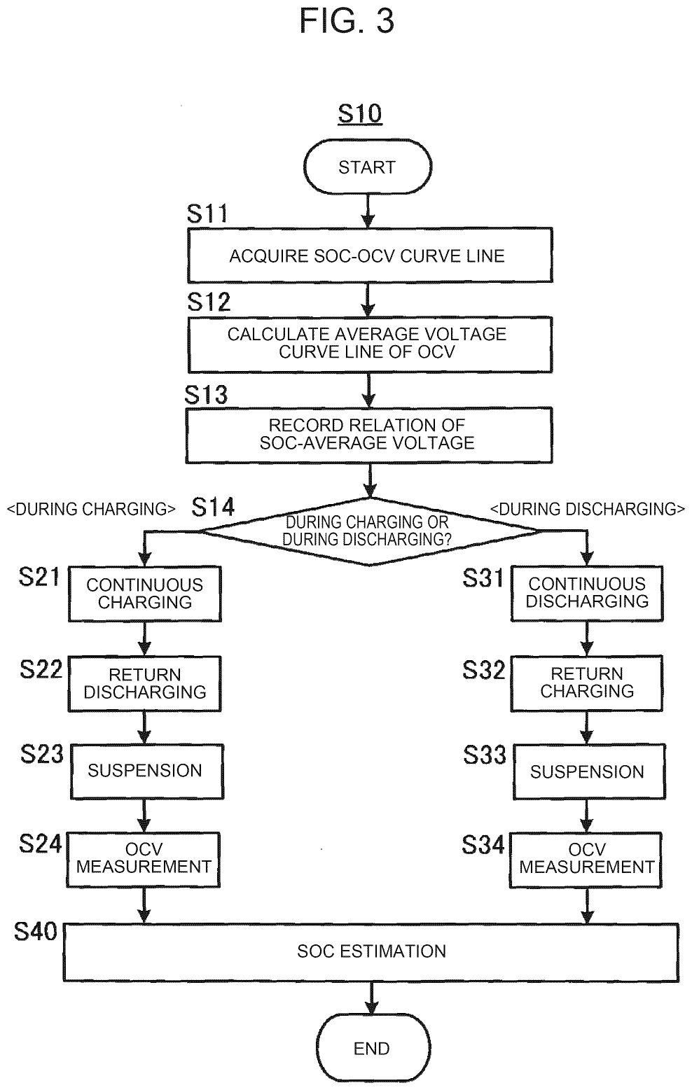

In the present embodiment, the battery charging rate estimation method is executed by operating the estimation device 20 described above. FIG. 3 shows a flow of an estimation method S10 for the charging rate of a battery according to one embodiment. However, the battery charging rate estimation method of the present disclosure does not necessarily have to be executed by the estimation device 20 described above, and may be executed by another device. Each step will be described below.

### 3.1. Acquisition of SOC-OCV Curve Line (Step S11)

In step S11 of acquiring an SOC-OCV curve line, the relation between SOC and OCV during charging/discharging is acquired. For example, acquisition of this curve line means acquisition of a curve line “during charging” and a curve line “during discharging” in FIG. 2. In other words, OCV during charging and OCV during discharging are obtained for each SOC at a predetermined interval.

Note that the values acquired in step S11 do not have to be acquired each time the SOC is estimated, and a value acquired and recorded initially can be reused.

### 3.2. Calculation of Average Voltage Curve Line of OCV (Step S12)

In step S12 of calculating an average voltage curve line of OCV, for the OCVs acquired in step S11, an average value of OCV during charging and OCV during discharging is calculated for each SOC. This results in a curve line based on the average voltage of OCV for each SOC (average voltage curve line) as indicated by “average value” in FIG. 2.

Note that the average voltage curve line of OCV acquired in step S12 does not need to be acquired each time SOC is estimated, and it is possible to reuse an average voltage curve line of OCV which was initially acquired and recorded.

### 3.3. Recording of SOC-Average Voltage Relation (Step S13)

In step S13 of recording an SOC-average voltage relation, the relation between the SOC and the average voltage of the OCV acquired in step S12 is recorded. The above relation is recorded in, for example, the ROM of the computer described above.

The form of the SOC-average voltage relation to be recorded is not particularly limited, and may be a formula obtained by formulating the average voltage curve line of OCV, or a map obtained by assigning a specific average voltage value to each SOC.

### 3.4. Determination on Which One of Charging and Discharging Is Being Performed (step S14)

In step S14, as a preparation step to estimate SOC, a determination is made as to whether the estimation is performed based on charging or based on discharging. The determination may be made according to the situation at the time, and when charging is currently being performed, the controller 23 selects “during charging”, and proceeds to step S21. When discharging is currently being performed, the controller 23 selects “during discharging”, and proceeds to step S31. However, the present disclosure is not limited to this style, and which one of step S21 and step S31 the process should proceed to may be determined based on a predetermined condition by the controller 23.

A case where the process antecedently proceeds to step S21 and then proceeds to step S31 will be described below.

### 3.5. Continuous Charging (Step S21)

In continuous charging step S21, continuous charging is performed on a battery at a predetermined ratio to the battery capacity (SOC 100%) by the charging/discharging unit 21 in response to a command from the controller 23. An image is also shown in FIG. 2. It is possible to preferably increase the SOC in the range of 5% to 20% as the predetermined ratio. In other words, for example, continuous charging is performed such that the SOC increases by 10% or more. The increase value in the SOC caused by the continuous charging performed here does not need to be highly accurate, and it is needed only to more reliably obtain an increase of SOC that is equal to or greater than a determined increase of SOC.

### 3.6. Return Discharging (Step S22)

In a return discharging step S22, discharging is performed by the controller 23 after the continuous charging is completed in the above step 21 (for convenience, this is referred to as “return discharging”). An image is also shown in FIG. 2. The return discharging is at least 2% or more of the battery capacity, preferably 3% or more, and more preferably 5% as shown in the following test example (it does not have to be strictly 5%, but it is in the range of 4% to 6%).

On the other hand, it is preferable that the magnitude (%) of the return discharging does not exceed the magnitude (%) of the continuous charging performed in step S21.

### 3.7. Suspension (Step S23)

In suspension step S23, after the return discharging is completed in step S22, the controller 23 stops charging and discharging, and leaves (suspends) for a predetermined period of time. The predetermined period of time is not particularly limited, but it may be set to 30 minutes or more. Long suspension is allowed, and there is no need to limit the upper limit. However, suspension for a certain period of time or more will reduce the effect, and thus it is waste of time.

Inclusion of such suspension step S23 makes it possible to eliminate polarization in the battery more reliably.

### 3.8. OCV Measurement (Step S24)

In OCV measurement step S24, the OCV (open circuit voltage) of the battery 10 at that time is measured from the voltage measurement unit 22 by the controller 23, and the value thereof is acquired by the controller 23.

### 3.9. Continuous Discharge (Step S31)

In continuous discharge step S31, continuous discharge of a predetermined ratio to the battery capacity (SOC 100%) is performed on the battery in response to a command from the controller 23 by the charging/discharging unit 21. An image is also shown in FIG. 2. The SOC is preferably reduced in the range of 5% to 20% as the predetermined ratio. In other words, for example, continuous discharge is performed such that the SOC is reduced by 10% or more. The reducing ratio of the SOC by the continuous discharge performed here does not need to be highly accurate, and it is needed only to more reliably obtain the same level as a predetermined SOC reduction or more.

### 3.10. Return Charging (step S32)

In return charging step S32, charging is performed by the controller 23 after the continuous discharging is completed in the above step 31 (here, for convenience, this is referred to as “return charging”). An image is also shown in FIG. 2. The return charging is defined as discharging of at least 2% or more of the battery capacity, preferably 3% or more, and more preferably 5% as shown in the following test example (it does not have to be strictly 5%, but it is in the range of 4% to 6%).

Furthermore, it is preferable that the magnitude (%) of the return charging does not exceed the magnitude (%) of the continuous discharge performed in step S31.

### 3.11. Suspension (Step S33)

In suspension step S33, after the return charging is completed in step S32, the controller 23 stops charging and discharging, and leaves (suspends) for a predetermined period of time. The predetermined period of time is not particularly limited, but it may be set to 30 minutes or more. Long suspension is allowed, and there is no need to limit the upper limit. However, suspension for a certain period of time or more will reduce the effect, and thus it is waste of time.

Inclusion of such suspension step S33 makes it possible to eliminate polarization in the battery more reliably.

### 3.12. OCV Measurement (Step S34)

In OCV measurement step S34, the OCV (open circuit voltage) of the battery 10 at that time is measured from the voltage measurement unit 22 by the controller 23, and the value thereof is acquired by the controller 23.

### 3.13. SOC Estimation (Step S40)

In SOC estimation step S40, the controller 23 applies the OCV obtained in step S24 or step S34 to the relation recorded in step S13 to calculate the value of SOC (corresponding to an estimated value). For example, when the OCV obtained in step S24 or step S34 is A (V) in FIG. 2, the SOC is estimated to be B (%) using the average value curve line.

### 4. Test Example

The inventor actually prepared a battery according to one example, and conducted a test for estimating SOC (charging rate, remaining battery capacity) when the process in step S14 proceeded to the continuous charging step S21 and SOC when the process in step S14 proceeded to the continuous discharging step S31.

### 4. 1 Battery

A battery to be tested was prepared as follows.

### Positive Electrode

Lithium nickelate coated with a solid-state electrolyte was used as a positive electrode active material, and the positive electrode active material, solid-state electrolyte, conductive additive, binder, and dispersant were added into dispersion liquid such that the weight ratio thereof was equal to 84.7:7.6:5.3:2.0:0.4, and kneaded to prepare a slurry. At this time, the solid content ratio was adjusted to 76%. This slurry was coated on aluminum foil as a current collector foil by using a blade having a coating gap of 350 μm.

### Negative Electrode

Si, solid electrolyte, conductive additive, binder, and the dispersant were added into dispersion liquid such that the weight ratio thereof was equal to 52.9:44.1:0.3:1.5:1.2, and kneaded to prepare a slurry. The solid content ratio at this time was set to 30%. This slurry was coated onto Ni foil as a current collector foil by using a blade having a coating gap of 450 μm.

### Separator

Sulfide solid-state electrolyte and binder were added into a dispersion liquid such that the weight ratio thereof was equal to 99.1:0.9, and kneaded to prepare a slurry. The solid content ratio at this time was adjusted to 38%. This slurry was coated onto an aluminum foil by using a blade having a coating gap of 75 μm.

### Preparation of Battery

A separator was transferred onto each of the positive electrode and the negative electrode by passing (roll-pressing) the separator through rolls having a gap of 70 μm once. The temperature at this time was 175° C. and the pressure was 5 t/cm.

After the transfer, the positive electrode was punched out to have a diameter of 11.28 mm, and the negative electrode was punched out to have a diameter of 11.74 mm to produce circular electrodes.

Furthermore, the separator was transferred to each electrode by uniaxial pressing. The temperature at this time was room temperature, the pressing pressure was 10 kN, and the pressing time was 10 seconds.

Thereafter, the positive electrode and the negative electrode were bonded to each other by uniaxial pressing. At this time, the bonding was performed in two separate press steps of a first press step and a second press step after the first press step. In the first press step, the temperature was set to 170° C., the press pressure was set to 1 kN, and the press time was set to 180 seconds, and in the second press step, the temperature was set to 170° C., the press pressure was set to 50 kN, and the press time was set to 60 seconds.

The laminate of the bonded positive and negative electrodes was sealed in a bag made of laminate foil to form a laminate cell. As a restraining condition, the laminate was first restrained at 20 MPa and held for 1 minute, and then maintained at a restraining force of 0.3 MPa.

### 4.2. Test 1

The average voltage relation between SOC and OCV was obtained in advance in steps S11 to S13, and then steps S21 to S24 were performed. Each step is as follows.
Step S13: On the obtained curve line, the average voltage of OCV at 49% of SOC was 3.393 V, and the average voltage of OCV at 51% of SOC was 3.412 V.
Step S21: Continuous charging was performed from a state where SOC was 0% until SOC reached 55%.
Step S22: The return discharging of 5% SOC was performed. In other words, SOC is theoretically 50%.
Step S23: The suspension time was set to 2 hours.

When OCV was measured according to step S24, a value of 3.399 V was obtained. It is found that this value is within the range of 3.393 V (SOC 49%) to 3.412 V (SOC 51%) on the curve line obtained in step S13, and it is within ±1%.

### 4.3. Test 2

The average voltage relation between SOC and OCV was obtained in advance in steps S11 to S13, and steps S31 to S34 were performed. Each step is as follows.
Step S13: On the obtained curve line, the average voltage of OCV at SOC 49% was 3.393 V, and the average voltage of OCV at SOC 51% was 3.412 V.
Step S31: Continuous discharging was performed from a state where SOC was 95% until SOC reached 45%.
Step S32: The return charging of 5% SOC is performed. In other words, SOC is theoretically 50%.
Step S33: The suspension time was set to 2 hours.

When OCV was measured according to step S34, a value of 3.393 V was obtained. It was found that this value is within a range of 3.393 V (SOC 49%) to 3.412 V (SOC 51%) on the curve line obtained in step S13, and is within ±1%.

### 4. 3 Text 3

The average voltage relation between SOC and OCV was obtained in advance in steps S11 to S13, and steps S21 to S24 were performed. Each step is as follows.
Step S13: On the obtained curve line, the average voltage of OCV at SOC 13% was 3.06 V.
Step S21: Continuous charging was performed from a state of SOC 0% until SOC reached 20%.
Step S22: Return discharging of SOC 5% was performed. In other words, SOC is theoretically 15%.
Step S23: The suspension time was set to 2 hours.

When OCV was measured according to step S24, 3.066 V was obtained, and it was the same level as 3.06 V (SOC 13%) based on the curve line obtained in step S13, and an error could be set within 2%.

### 4.4. Test 4

The average voltage relation between SOC and OCV was obtained in advance in steps S11 to S13, and steps S21 to S24 were performed. Each step is as follows.
Step S13: On the obtained curve line, the average voltage of OCV at SOC 44% was 3.35 V.
Step S21: Continuous charging was performed from a state of SOC 0% until SOC reached 50%.
Step S22: The return discharging of 5% SOC was performed. In other words, SOC was theoretically 45%.
Step S23: The suspension time was set to 2 hours.

When OCV was measured according to step S24, 3.350 V could be obtained. It was equal to 3.35 V (SOC 14%) based on the curve line obtained in step S13, and an error could be set within 1%.

### 5. Effect and the Like

According to the present disclosure, even when the battery is deteriorated, the charging rate of the battery (remaining battery capacity) can be accurately estimated. This effect is particularly noticeable in batteries with large charge/discharge hysteresis (for example, when Si is used as the negative electrode active material, etc.).

The reason why such an effect is observed by the present disclosure is not necessarily clear, but for example, when Si is used as the negative electrode active material, the crystal phase state of Si during charging is different from that during discharging, so that the charge/discharge hysteresis becomes large. In addition to this, the return discharging after the continuous charging and the return charging after the continuous discharging are performed, whereby the crystal phase during charging and the crystal phase during discharging are mixed with each other, resulting in an average voltage between charging and discharging, which is considered as one of factors.

What is claimed is:

1. A method for estimating a charging rate of a battery, comprising:
a step of acquiring an SOC-OCV curve line for the battery having a charge/discharge hysteresis of Δ0.06V to 0.24V, calculating an average voltage of OCV for each SOC from an acquired result, and recording a relation between a calculation result and the SOC;
a step of performing continuous charging or continuous discharging on the battery;
a step of performing return discharging that is discharging of 3% or more of a total capacity of the battery when the continuous charging has been performed, and performing return charging that is charging of 3% or more of the total capacity of the battery when the continuous discharging has been performed; and
a step of measuring the OCV of the battery and checking a value of the OCV against the recorded relation between the SOC and the average voltage of the OCV to acquire an estimated value of the charging rate of the battery.

2. The method according to claim 1, wherein the return discharging and the return charging are from 4% to 6%.

3. The method according to claim 1, wherein after the return discharging and the return charging has been performed, charging and discharging of the battery is suspended for a predetermined period of time, and then an estimated value of the charging rate of the battery is acquired.
